(19) United States
(12) Patent Application Publication
(10) Pub. No.: US 2004/0217450 A1
(43) Pub. Date: Nov. 4, 2004

(54) Leadframe-based non-leaded semiconductor package and method of fabricating the same

(75) Inventors: Chun-Yuan Li, Taichung Hsien (TW); Terry Tsai, Taichung Hsien (TW); Holman Chen, Taichung Hsien (TW); Chin-Teng Hsu, Taichung Hsien (TW); Jui-Hsiang Hung, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd.

(21) Appl. No.: 10/618,015

(22) Filed: Jul. 11, 2003

(30) Foreign Application Priority Data
May 2, 2003 (TW) 092112093

(51) Int. Cl. H01L 21/44

(52) U.S. Cl. 257/666; 438/123

(57) ABSTRACT

A leadframe-based non-leaded semiconductor package and method of fabricating the same is proposed, which is used for the fabrication of a non-leaded type of semiconductor package, such as QFN (Quad Flat No-lead) package. The proposed semiconductor packaging technology is characterized by the provision of a recessed portion in the paddle portion of the leadframe to help secure the encapsulation body more firmly in position without delamination, as well as help lower the position of the packaged chip to help prevent the bonding wires from being exposed to the outside of the encapsulation body. These features can help the finished package to be more reliable with increased good yield.

### BACKGROUND OF THE INVENTION

1. Field of the Invention

This invention relates to semiconductor packaging technology, and more particularly, to a leadframe-based non-leaded semiconductor package and method of fabricating the same, which is used for the fabrication of a non-leaded type of semiconductor package, such as a QFN (Quad Flat No-lead) package.

2. Description of Related Art

QFN (Quad Flat No-lead) is an advanced type of semiconductor packaging technology which is characterized by the provision of non-protruding leads on the bottom side of the encapsulation body for external electrical coupling. Since the leads are non-protruding, the package body appears to be “non-leaded” and thus can help allow the overall package body to be made very compact in size. During SMT (Surface Mount Technology) process, the QFN package is mounted on a printed circuit board (PCB) and electrically connected to the same by means of the non-protruding pads on the bottom side of the package body.

Related art includes, for example, the following patents: U.S. Pat. No. 5,172,214 entitled “LEADLESS SEMICONDUCTOR DEVICE AND METHOD FOR MAKING THE SAME”; U.S. Pat. No. 6,229,200 entitled “SAW-SINGULATED LEADLESS PLASTIC CHIP CARRIER”; U.S. Pat. No. 6,143,981 entitled “PLASTIC INTEGRATED CIRCUIT PACKAGE AND METHOD AND LEADFRAME FOR MAKING THE PACKAG”; to name just a few.

FIG. 1 is a schematic diagram showing a sectional view of a first conventional type of leadframe-based QFN package which is based on the semiconductor packaging technology of U.S. Pat. No. 5,172,214. As shown, this QFN package comprises: (a) a leadframe 110 having a centrally-located paddle portion 111 and a peripherally-located lead portion (which includes a number of leads) 112 surrounding the paddle portion 111; (b) a semiconductor chip 120 mounted over the paddle portion 111 of the leadframe 110; (c) a set of bonding wires, typically gold wires 130 for electrically coupling the chip 120 to the lead portion 112 of the leadframe 110; and (d) an encapsulation body 140 for encapsulating the chip 120 and the gold wires 130 but exposing the bottom surface of the lead portion 112 and the bottom surface of the paddle portion 111.

One drawback to the foregoing QFN package of FIG. 1, however, is that the encapsulation body 140 would easily suffer from delamination due to thermal stress during high-temperature treatments, causing the formation of cracks 141, 142 between the encapsulation body 140 and the paddle portion 111 and the lead portion 112 of the leadframe 110, since there is a CTE mismatch (Coefficient of Thermal Expansion) between the leadframe 110 and the encapsulation body 140.

FIG. 2 shows a solution to the foregoing problem, which is based on the semiconductor packaging technologies of U.S. Pat. No. 6,229,200 and 6,143,981. As shown, the structure of this QFN package comprises: (a) a leadframe 210 having a centrally-located paddle portion 211 and a peripherally-located lead portion 212 surrounding the paddle portion 211; (b) at least one semiconductor chip 220 mounted over the paddle portion 211 of the leadframe 210; (c) a set of bonding wires 230 for electrically coupling the chip 220 to the lead portion 212 of the leadframe 210; and (d) an encapsulation body 240 for encapsulating the chip 220 and the gold wires 230 but exposing the bottom surface of the lead portion 212 and the bottom surface of the paddle portion 211. This QFN package is characterized by the formation of stepped portions 211a, 212a in the bottom surfaces of the paddle portion 211 and the lead portion 212 of the leadframe 210 and making the surfaces of the leadframe 210 rugged, which can help increase the strength of the bonding between the encapsulation body 240 and the leadframe 210, for the purpose of preventing delamination of the encapsulation body 240 off the leadframe 210.

One drawback to the forgoing QFN package structure of FIG. 2, however, is that when the leadframe 210 is made thinner in order to make the overall package size smaller in height, such as below 0.5 mm, delamination of the encapsulation body 240 off the leadframe 210 would nevertheless occur. As shown in FIG. 2, in the case of the package body being 0.5 mm in overall thickness, the leadframe 210 is 0.2 mm in thickness; the chip 220 is 0.15 mm in thickness, the loop height of the bonding wires 230 is 0.127 mm; and the part of the encapsulation body 240 above the bonding wires 230 is only 0.023 mm which would be highly likely to cause the bonding wires 230 to be exposed to the outside of the encapsulation body 240 which would make the finished package a defective one. If the leadframe 210 is downsized to 0.127 mm in thickness, it can help increase the part of the encapsulation body 240 above the bonding wires 230 to 0.096 mm. However, in this case, the stepped portions 211a, 212a of the leadframe 210 will become overly thin (0.127 mm), which would then easily cause delamination of the encapsulation body 240 off the leadframe 210.

Moreover, when the chip 220 is large in size, it requires the paddle portion 211 of the leadframe 210 to be increased in area, which would nevertheless cause delamination of the encapsulation body 240, since a larger paddle would incur a larger thermal stress.

### SUMMARY OF THE INVENTION

It is therefore an objective of this invention to provide a new semiconductor packaging technology that can be used for the fabrication of a leadframe-based non-leaded semiconductor package at a downsize level below 0.5 mm without delamination of the encapsulation body off the leadframe.

It is another objective of this invention to provide a new semiconductor packaging technology that can be used for the packaging of a large-size semiconductor chip without delamination of the encapsulation body.

It is still another objective of this invention to provide a new semiconductor packaging technology that can be used for the fabrication of a QFN package with a thin profile without having to reduce the overall thickness of the leadframe and without delamination of the encapsulation body.

The semiconductor packaging technology according to the invention is used for the fabrication of a leadframe-based non-leaded type of semiconductor package, such as a leadframe-based QFN (Quad Flat No-lead) package. The semiconductor packaging technology is characterized by the provision of a recessed portion in the paddle portion of the leadframe to help secure the encapsulation body more firmly in position without delamination, as well as help lower the position of the packaged chip to help prevent the bonding wires from being exposed to the outside of the encapsulation body. These features can help the finished package to be more reliable with increased good yield. The semiconductor packaging technology of the invention is therefore more advantageous to use than prior art.

### BRIEF DESCRIPTION OF DRAWINGS

The invention can be more fully understood by reading the following detailed description of the preferred embodiments, with reference made to the accompanying drawings, wherein:

FIG. 1 (PRIOR ART) is a schematic diagram showing a sectional view of a first conventional type of leadframe-based QFN package;

FIG. 2 (PRIOR ART) is a schematic diagram showing a sectional view of a second conventional type of leadframe-based QFN package; and

FIG. 3A is a schematic diagram showing a sectional view of a leadframe utilized by the semiconductor packaging technology according to the invention;

FIG. 3B is a schematic diagram showing a top view of the leadframe of FIG. 3A;

FIG. 3C is a schematic sectional diagram used to depict a die-mounting process involved in the semiconductor packaging technology according to the invention;

FIG. 3D is a schematic sectional diagram used to depict a wire-bonding process involved in the semiconductor packaging technology according to the invention;

FIG. 3E is a schematic sectional diagram used to depict an encapsulation process involved in the semiconductor packaging technology according to the invention.

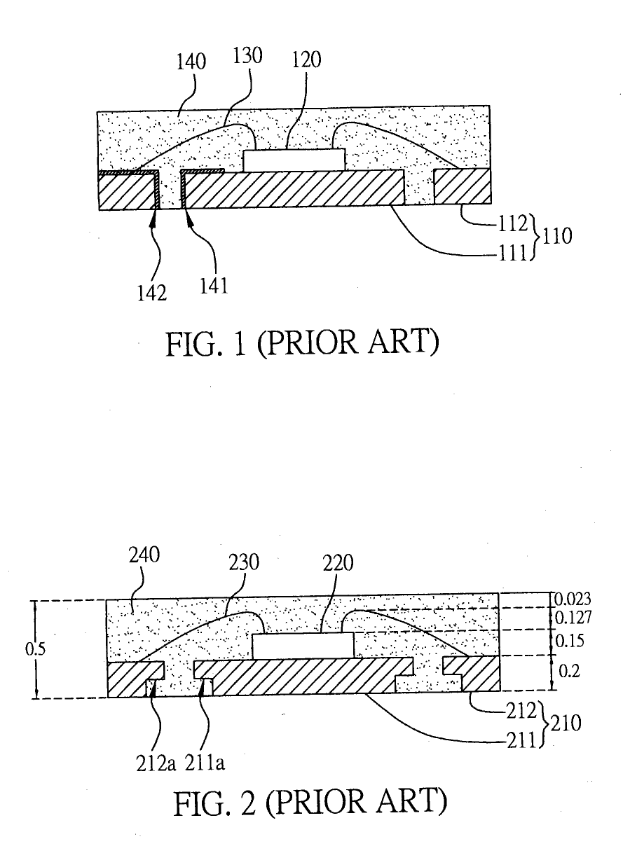

### DETAILED DESCRIPTION OF PREFERRED EMBODIMENTS

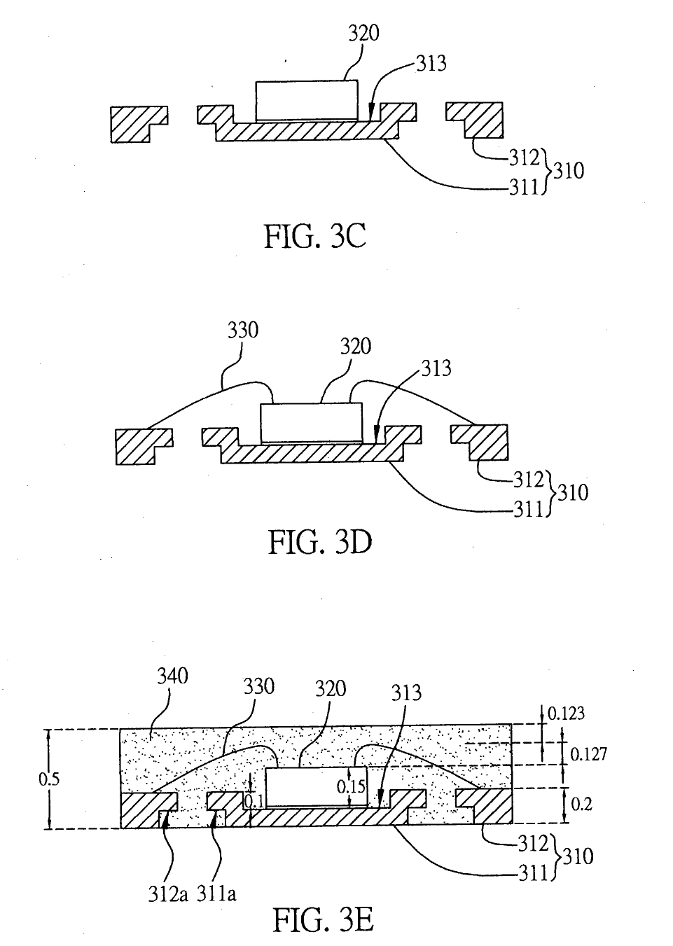

The semiconductor packaging technology according to the invention for fabricating a leadframe-based non-leaded semiconductor package is disclosed in full details by way of preferred embodiments in the following with reference to FIGS. 3A-3E. In the following preferred embodiment, the semiconductor packaging technology according to the invention will be used, for example, for the fabrication of a leadframe-based QFN (Quad Flat No-lead) package.

Referring first to FIG. 3A and FIG. 3B, by the method of the invention, the first step is to prepare a leadframe 310 of the type having a centrally-located paddle portion 311 and a peripherally-located lead portion (which includes a number of leads) 312 surrounding the paddle portion 311. The invention is characterized in that the paddle portion 311 of the leadframe 310 is formed with a recessed portion 313 on one surface thereof through, for example, a half-etch process by which the front surface of the paddle portion 311 is etched to a predefined depth. In the case of the leadframe 310 being 0.2 mm in overall thickness, for example, the recessed portion 313 is etched to a depth of about 0.1 mm. Further, the paddle portion 311 and the lead portion 312 of the leadframe 310 can also be formed with stepped portions 311a, 312a.

Referring further to FIG. 3C, in the subsequent step, a die-mounting process is performed to mount at least one semiconductor chip 320 in the recessed portion 313 over the paddle portion 311 of the leadframe 310. The semiconductor chip 320 has a thickness of, for example, 0.15 mm.

Referring further to FIG. 3D, in the next step, a wire-bonding process is performed to electrically couple the semiconductor chip 320 to the lead portion 312 of the leadframe 310 by means of bonding wires, such as gold wires 330. The loop height of the gold wires 330 is, for example, 0.127 mm.

Referring finally to FIG. 3E, in the final step, a molding process is performed to form a molded compound (M/C) serving as an encapsulation body 340 for encapsulating the semiconductor chip 320 and the gold wires 330 while exposing the back side of the lead portion 312 and the paddle portion 311. This completes the fabrication of a QFN package.

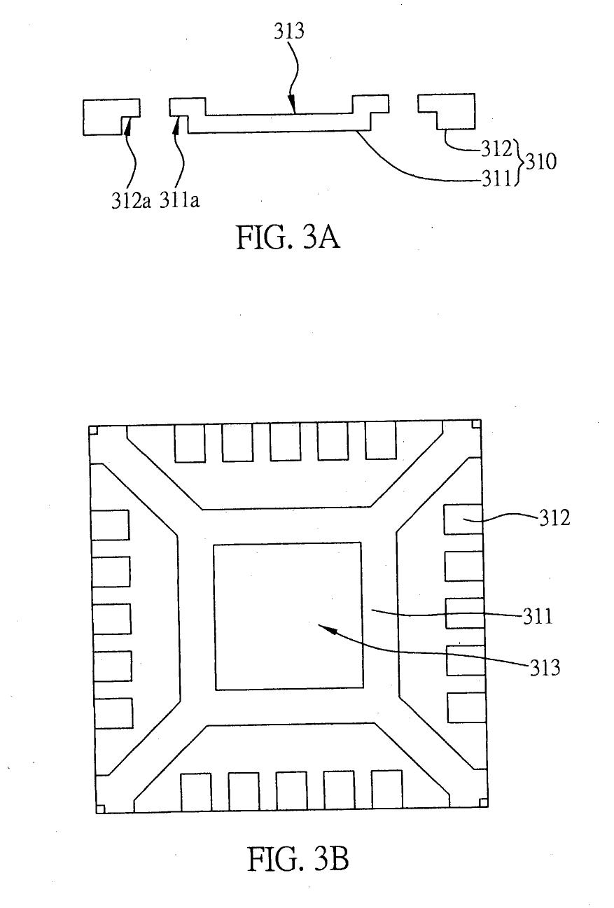

As the QFN package is finished, it can be seen from FIG. 3E that the recessed portion 313 acts as a locking structure to the encapsulation body 340 and therefore can help secure the encapsulation body 340 firmly in position without delamination. Moreover, since the formation of the recessed portion 313 can help lower the position of the packaged chip 320 and therefore can help increase the height of the part of the encapsulation body 340 above the gold wires 330 to 0.123 mm as compared to the 0.023 mm in the case of the prior art of FIG. 2, which can help prevent the bonding wires from being exposed to the outside of the encapsulation body.

In conclusion, the invention provides a new semiconductor packaging technology for the fabrication of a leadframe-based non-leaded semiconductor package, such as a QFN package, and which is characterized by the provision of a recessed portion in the paddle portion of the leadframe to help secure the encapsulation body more firmly in position without delamination, as well as help lower the position of the packaged chip to help prevent the bonding wires from being exposed to the outside of the encapsulation body. These features can help the finished package to be more reliable with increased good yield. The invention is therefore more advantageous to use than prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A leadframe-based non-leaded semiconductor package, which comprises:
a leadframe having a centrally-located paddle portion and a peripherally-located lead portion surrounding the paddle portion, and wherein the paddle is formed with a recessed portion to a predetermined depth in one surface thereof;
at least one semiconductor chip mounted in the recessed portion of the paddle portion of the leadframe;
a set of bonding wires for electrically coupling the semiconductor chip to the lead portion of the leadframe; and
an encapsulation body for encapsulating the semiconductor chip and the bonding wires while exposing a surface of the lead portion of the leadframe.

2. The leadframe-based non-leaded semiconductor package of claim 1, wherein the recessed portion in the paddle portion of the leadframe is formed through a half-etch process.

3. The leadframe-based non-leaded semiconductor package of claim 1, wherein the bonding wires are gold wires.

4. The leadframe-based non-leaded semiconductor package of claim 1, wherein the leadframe is further formed with stepped portions in the paddle portion and the lead portion thereof.

5. A method for fabricating a leadframe-based non-leaded semiconductor package, comprising the steps of:
(1) preparing a leadframe having a centrally-located paddle portion and a peripherally-located lead portion surrounding the paddle, and wherein the paddle is formed with a recessed portion to a predetermined depth in one surface thereof;
(2) mounting at least one semiconductor chip in the recessed portion of the paddle portion of the leadframe;
(3) electrically coupling the semiconductor chip to the leadframe; and
(4) forming an encapsulation body for encapsulating the semiconductor chip while exposing a surface of the lead portion of the leadframe.

6. The method of claim 5, wherein in said step (1), the recessed portion in the paddle portion of the leadframe is formed through a half-etch process.

7. The method of claim 5, wherein in said step (1) the leadframe is further formed with stepped portions in the paddle portion and the lead portion thereof.

8. The method of claim 5, wherein in said step (3), the semiconductor chip is electrically coupled to the leadframe by means of a set of bonding wires through a wire-bonding process.

9. The method of claim 8, wherein the bonding wires are gold wires.
